(19) United States
(12) Patent Application Publication
(10) Pub. No.: US 2026/0202482 A1
(43) Pub. Date: Jul. 16, 2026

(54) BATTERY MANAGEMENT SYSTEM

(71) Applicant: TOYOTA JIDOSHA KABUSHIKI KAISHA, Toyota-shi (JP)

(72) Inventors: Yoshiaki KIKUCHI, Toyota-shi (JP); Ryo Mano, Nisshin-shi (JP); Hiroki Tashiro, Nisshin-shi (JP); Yuji Nishi, Nagoya-shi (JP); Keisuke Ishikawa, Nagakute-shi (JP)

(73) Assignee: TOYOTA JIDOSHA KABUSHIKI KAISHA, Toyota-shi (JP)

(21) Appl. No.: 19/409,989

(22) Filed: Dec. 5, 2025

(30) Foreign Application Priority Data
Jan. 14, 2025 (JP) 2025-004697

(51) Int. Cl. G01R 31/389; G01N 27/02; G01R 31/378; G01R 31/385; G01R 31/392; H01M 10/42

(52) U.S. Cl. CPC G01R 31/389; G01N 27/021; G01R 31/378; G01R 31/386; G01R 31/392; H01M 10/4221; H01M 10/425; H01M 2010/4271

(57) ABSTRACT

A battery management system according to the present disclosure includes a three-phase inverter, and an impedance detecting unit that detects two or more peak voltages of a high frequency signal in a lithium-ion secondary battery and calculates an attenuation characteristic, and detects, from the calculated attenuation characteristic, a real part of an alternating current impedance used to calculate amount of Li deposition, and further includes a control unit that supplies an alternating current signal that is a test signal generated by the three-phase inverter to the lithium ion secondary battery in test mode, and a correction unit that performs correction of a value of peak voltage of the high-frequency signal corresponding to the test signal that is detected by the impedance detecting unit, based on difference between peak voltage of the test signal detected by the impedance detecting unit and a theoretical value of peak voltage of the test signal.

### CROSS-REFERENCE TO RELATED APPLICATION

This application claims priority to Japanese Patent Application No. 2025-004697 filed on January 14, 2025. The disclosure of the above-identified application, including the specification, drawings, and claims, is incorporated by reference herein in its entirety.

### BACKGROUND

### 1. Technical Field

The present disclosure relates to a battery management system.

### 2. Description of Related Art

In order to suppress deterioration of performance of lithium-ion secondary batteries, there is a need to suppress increase in Li (lithium) deposited in the lithium-ion secondary batteries due to rapid charging or the like. In recent years, development of technology for detecting lithium deposition inside lithium-ion secondary batteries is also being advanced, as described in Japanese Unexamined Patent Application Publication No. 2022-108602 (JP 2022-108602 A).

### SUMMARY

There continues to be demand for precise detection of Li deposited in lithium-ion secondary batteries.

The present disclosure has been made in light of the above circumstances, and an object thereof is to provide a battery management system that is capable of precisely detecting Li deposited in a lithium-ion secondary battery.

A battery management system according to the present disclosure includes at least a three-phase inverter driven by power from a lithium-ion secondary battery, and an impedance detecting unit that detects two or more peak voltages of a high-frequency signal in the lithium-ion secondary battery, calculates an attenuation characteristic, and detects, from the attenuation characteristic that is calculated, a value of a real part of an alternating current impedance used to calculate an amount of Li deposition, and the battery management system further includes a control unit that supplies an alternating current signal that is a test signal generated by the three-phase inverter to the lithium-ion secondary battery in a test mode, and a correction unit that performs correction of a value of peak voltage of the high-frequency signal corresponding to the test signal that is detected by the impedance detecting unit, based on a difference between the peak voltage of the test signal detected by the impedance detecting unit and a theoretical value of the peak voltage of the test signal. The battery management system according to the present disclosure can precisely detect Li that is deposited in a lithium-ion secondary battery by performing correction of detection error of the impedance detecting unit that detects the value of the real part of the alternating current impedance used to calculate the amount of Li deposited.

The present disclosure enables a battery management system to be provided that is capable of precisely detecting Li deposited in a lithium-ion secondary battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a configuration example of a battery management system according to a first embodiment;

FIG. 2 is a diagram showing a relation between state of health (SOH) of a secondary battery and an amount of change in a real part Z of alternating current impedance when a high-frequency signal of 1 MHz is supplied to the secondary battery;

FIG. 3 is a diagram showing a relation between frequency of alternating current signals that are supplied to a secondary battery and the real part of the alternating current impedance that is detected from the secondary battery;

FIG. 4 is a diagram showing a relation between frequency of alternating current signals that are supplied to a secondary battery and the real part of the alternating current impedance that is detected from the secondary battery;

FIG. 5 is a diagram illustrating a specific configuration example of an impedance detecting unit provided in a battery management device according to the first embodiment;

FIG. 6 is a diagram showing attenuation characteristics of a high-frequency signal supplied from a high-frequency signal supplying unit to a secondary battery when calculating an amount of Li deposition;

FIG. 7 is a timing chart for explaining detection error of peak voltage Vo caused by feedback delay;

FIG. 8 is a timing chart for explaining detection error of the peak voltage Vo caused by sensitivity of a comparator A2; and

FIG. 9 is a timing chart for describing detection error of the peak voltage Vo caused by noise.

### DETAILED DESCRIPTION OF EMBODIMENTS

A specific embodiment to which the present disclosure is applied will be described in detail below with reference to the drawings. Note, however, that the present disclosure is not limited to the following embodiments. Also, the following description and drawings are simplified as appropriate for clarity of description.

### First Embodiment

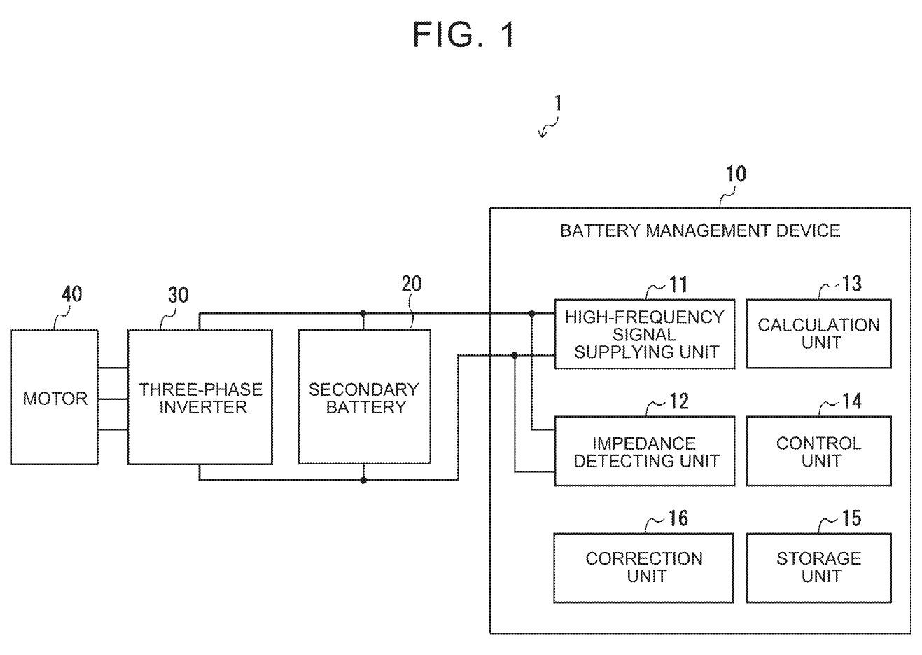

FIG. 1 is a block diagram illustrating a configuration example of a battery management system according to a first embodiment. As illustrated in FIG. 1, the battery management system 1 includes a battery management device 10, a secondary battery 20 that is managed by the battery management device 10, and a three-phase inverter 30 that is driven by power from the secondary battery 20. FIG. 1 also illustrates a motor 40 that is driven by the three-phase inverter.

The secondary battery 20 is a lithium-ion secondary battery, and is made up of a cell stack of a plurality of battery cells that is stacked, and a case that houses the cell stack.

Each of the battery cells includes a cathode, an anode, and an ionic transmission medium that is provided between the cathode and the anode, and that conducts carrier ions. A separator may further be provided between the cathode and the anode. The separator is made of a resin such as polyethylene, polypropylene, or the like.

For a cathode active material, for example, a sulfide containing a transition metal element, an oxide containing lithium and a transition metal element, or the like, are used. Specifically, for the cathode active material, lithium manganese composite oxides with a basic composition formula such as Li₍₁₋ₓ₎MnO₂ (where 0 < x < 1), Li₍₁₋ₓ₎Mn₂O₄, or the like, lithium cobalt composite oxides with a basic composition formula such as Li₍₁₋ₓ₎CoO₂ or the like, lithium nickel composite oxides with a basic composition formula such as Li₍₁₋ₓ₎NiO₂, or the like, or lithium nickel cobalt manganese composite oxides with a basic composition formula such as Li₍₁₋ₓ₎NiₐCo_{b}Mn_{c}O₂ (where a + b + c = 1) or the like, and so forth are used. Note that for the cathode active material, a substance may be used that is obtained by including other elements in the above basic composition formulas. Aluminum (Al) or the like, for example, is used for a cathode current collector.

For an anode active material, for example, a composite oxide containing lithium, a carbon material, or the like, is used. Specifically, for the anode active material an inorganic compound such as lithium, lithium alloys, tin compounds, or the like, a carbon material that is capable of absorbing and releasing lithium ions, a composite oxide containing a plurality of elements, a conductive polymer, and so forth, are used. Examples of carbon materials that are used for the anode active material include cokes, glassy carbons, graphites, non-graphitizable carbons, pyrolytic carbons, carbon fibers, and so forth, with graphites, such as artificial graphite, natural graphite, and so forth being preferred. Also, examples of the composite oxide that is used for the anode active material include lithium titanium composite oxides, lithium vanadium composite oxides, and so forth. Copper (Cu) or the like, for example, is used for an anode current collector.

An ionically conductive medium is used as an electrolytic solution, by dissolving a supporting salt, for example. For the supporting salt, for example, a lithium salt such as LiPF₆, LiBF₄, or the like, is used. For a solvent for the electrolytic solution, for example, any one of carbonates, esters, ethers, nitriles, furans, sulfolanes, and dioxolanes, or a mixture of several of these, is used. Examples of carbonates include cyclic carbonates such as ethylene carbonate, propylene carbonate, vinylene carbonate, butylene carbonate, chloroethylene carbonate, and so forth, and chain carbonates such as dimethyl carbonate, ethyl methyl carbonate, diethyl carbonate, ethyl-n-butyl carbonate, methyl-t-butyl carbonate, di-i-propyl carbonate, t-butyl-i-propyl carbonate, and so forth. Alternatively, for the ionically conductive medium, a solid ionically conductive polymer, an inorganic solid electrolyte, a mixed material of an organic polymer electrolyte and an inorganic solid electrolyte, an inorganic solid powder that is bound by an organic binder, or the like, may be used.

The battery management device 10 performs charging management of the secondary battery 20 that is to be managed. For example, the battery management device 10 non-destructively detects the amount of Li deposited in the secondary battery 20, and performs feedback control of allowable charging power (upper limit of charging power) Pa for the secondary battery 20, based on the detection results.

Specifically, the battery management device 10 includes a high-frequency signal supplying unit 11, an impedance detecting unit 12, a calculation unit 13, a control unit 14, a storage unit 15, and a correction unit 16.

The high-frequency signal supplying unit 11 supplies high-frequency signals to the secondary battery 20. The impedance detecting unit 12 detects a value of a real part Z of the alternating current impedance from the secondary battery 20 to which the high-frequency signals are supplied. The high-frequency signal supplying unit 11 may be part of the impedance detecting unit 12, which will be described later.

Now, in the secondary battery 20, metallic Li is deposited on electrode surfaces of the battery cells as a result of repeated charging. The greater the charging power is set in order to increase the charging speed, the more the Li deposition advances, which causes state of health (SOH) of the secondary battery 20 to deteriorate. Note that the SOH of the secondary battery 20 refers to the percentage of the current capacity of the secondary battery 20, with initial capacity thereof as 100%. Accordingly, setting the secondary battery 20 to the highest possible allowable charging power Pa that allows efficient charging in the shortest possible charging time, while suppressing Li deposition, is desirable.

Now, when an alternating current signal (high-frequency signal), of such a high frequency that diffusion, reaction, and movement of lithium ions in each of the battery cells of the secondary battery 20 cannot keep up, is supplied to the secondary battery 20, the current of the high-frequency signal flows along edges of conductors in each of the battery cells due to the skin effect. In other words, the current of the high-frequency signal flows over electrode surfaces of each of the battery cells, on which Li is readily deposited, due to the skin effect. Also, even when Li metal is electrically disconnected from the anode after Li deposition, and is in a floating state, a current still flows over the Li metal due to inductive coupling and capacitive coupling. Therefore, for example, the smaller the amount of Li deposition is, the lower the electrical conductivity of the electrode surface of each of the battery cells is, and accordingly the greater the value of the real part Z of the alternating current impedance will be, while the greater the amount of Li deposition is, the higher the electrical conductivity of the electrode surface of each of the battery cells is, and accordingly the smaller the value of the real part Z of the alternating current impedance will be. Now, a great amount of current is concentrated on the Li metal, which has high electrical conductivity, and accordingly magnetic fields change around Li deposition regions, which is accompanied by eddy currents being generated. Such eddy currents cause loss in conductive portions of current collecting foils and electrodes, but reduce loss in the battery as a whole. Accordingly, the greater the amount of Li deposition is, the greater the change in the magnetic field is, and accordingly the greater the eddy currents become, the smaller the value of the real part Z will be. Hence, the amount of Li deposition in the secondary battery 20 can be calculated from the value of the real part Z of the alternating current impedance that is detected from the secondary battery 20 to which the high-frequency signals are supplied. Once the amount of Li deposition is known, the SOH of the secondary battery 20 can also be estimated.

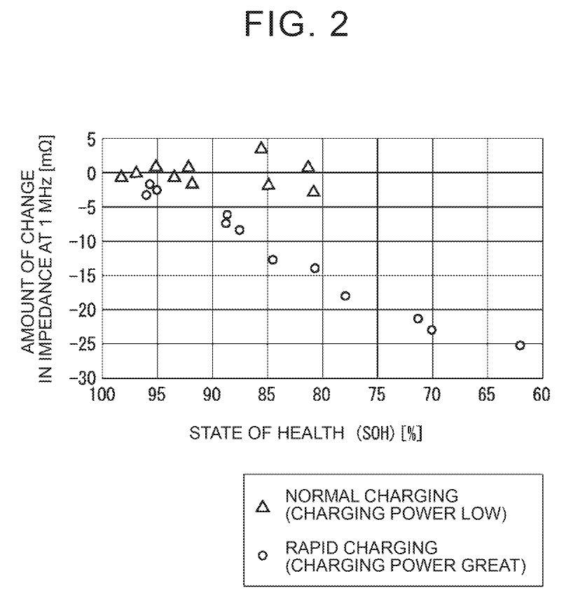

FIG. 2 is a diagram showing a relation between the SOH of the secondary battery 20 and the amount of change in the real part Z of the alternating current impedance (difference between detected value and initial value) when a high-frequency signal of 1 MHz is supplied to the secondary battery 20. As indicated by triangle marks in FIG. 2, in the case of normal charging with a small charging power, the amount of Li deposition is small even when charging is repeated, and accordingly the amount of change in the real part Z of the alternating current impedance remains small even when deterioration of the SOH advances due to some other factor (i.e., the detected value of the real part Z of the alternating current impedance is maintained at a high value). In contrast, as indicated by circle marks in FIG. 2, in the case of rapid charging with a great charging power, the amount of Li deposition increases with repeated charging, and accordingly, the deterioration of the SOH advances and the amount of change in the real part Z of the alternating current impedance becomes great (i.e., the detected value of the real part Z of the alternating current impedance becomes low). Note that when Li deposition is predominant among causes of the battery deterioration, the amount of Li deposition can be derived from the SOH. Alternatively, the SOH can be derived from the amount of Li deposited.

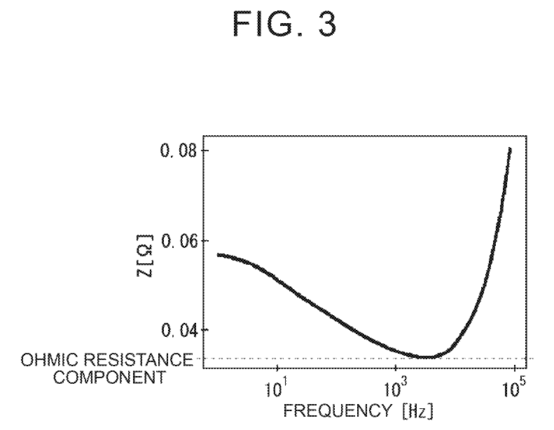

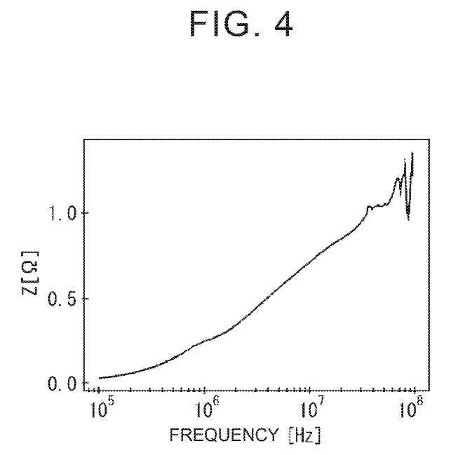

FIGS. 3 and 4 are diagrams showing a relation between frequency of alternating current signals that are supplied to the secondary battery 20 and the real part of the alternating current impedance that is detected from the secondary battery 20. FIG. 3 shows the value of the real part Z of the alternating current impedance when alternating current signals ranging from 1 kHz to 100 kHz are supplied to the secondary battery 20. FIG. 4 shows the value of the real part Z of the alternating current impedance when alternating current signals ranging from 100 kHz to 100 MHz are supplied to the secondary battery 20.

As shown in FIG. 3, when an alternating current signal of around 1 kHz is supplied to the secondary battery 20, the value of the real part Z of the alternating current impedance indicates a minimum value. An impedance component at this time represents an ohmic resistance component. Also, as shown in FIGS. 3 and 4, as the frequency of the alternating current signal that is supplied to the secondary battery 20 increases, the skin effect causes the current flow to concentrate on the electrode surface of each of the cells, and accordingly the value of the real part Z of the alternating current impedance increases.

Accordingly, the high-frequency signal supplying unit 11 supplies the secondary battery 20 with an alternating current signal (i.e., high-frequency signal) having such a high frequency that the value of the real part Z of the alternating current impedance, which is sufficiently high as compared to the ohmic resistance component, can be detected. For example, the high-frequency signal supplying unit 11 supplies a high-frequency signal of 0.1 MHz or higher to the secondary battery 20. Alternatively, the high-frequency signal supplying unit 11 supplies to the secondary battery 20 a high-frequency signal of a frequency such that the value of the real part of the alternating current impedance detected is 10 times or more greater, due to the skin effect, as compared to the value of the real part Z of the alternating current impedance detected when an alternating current signal of 1 kHz is supplied to the secondary battery 20. In the examples in FIGS. 3 and 4, the high-frequency signal supplying unit 11 supplies the secondary battery 20 with a high-frequency signal of 0.5 MHz or higher. Accordingly, the current of the high-frequency signal flows over the electrode surface (Li deposition region) of each of the battery cells of the secondary battery 20, due to the skin effect. This enables the impedance detecting unit 12 to detect the real part Z of the alternating current impedance in accordance with the amount of Li deposition.

The calculation unit 13 calculates the amount of Li deposited in the secondary battery 20 from the value of the real part Z of the alternating current impedance detected by the impedance detecting unit 12. More specifically, the calculation unit 13 calculates the amount of Li deposition in the secondary battery 20 based on difference between the current value of the real part Z of the alternating current impedance detected by the impedance detecting unit 12 and the initial value of the real part Z of the alternating current impedance of the secondary battery 20. Information regarding the initial value of the real part Z of the alternating current impedance of the secondary battery 20 to be managed is stored in the storage unit 15, for example.

For example, the greater the value of the real part Z of the alternating current impedance that is detected is, the smaller the amount of Li deposition that is calculated by the calculation unit 13 is, and the smaller the value of the real part Z of the alternating current impedance that is detected is, the greater the amount of Li deposition that is calculated is.

Note that the storage unit 15 may store information regarding the initial value of the real part Z of the alternating current impedance of each type of secondary battery. Alternately, the storage unit 15 may store map information that represents a relation between difference (amount of change) between the current value (detected value) and the initial value of the real part Z of the alternating current impedance of each type of secondary battery, and the amount of Li deposition. This map information is, for example, information that is obtained through experimentation or the like in advance, but may be updated as appropriate based on information detected from the secondary battery 20 to be managed. In this case, the calculation unit 13 extracts the amount of Li deposition corresponding to the value of the real part Z of the alternating current impedance, detected by the impedance detecting unit 12, from the map information stored in the storage unit 15.

The control unit 14 controls the allowable charging power Pa for the secondary battery 20, based on the amount of Li deposition calculated by the calculation unit 13. For example, when the calculated amount of Li deposition is small, progress of Li deposition is being suppressed, and accordingly the control unit 14 controls the allowable charging power Pa either to be maintained at the current level thereof or to be higher, and the greater the calculated amount of Li deposition is, the greater the necessity is to suppress the progress of Li deposition, and accordingly the allowable charging power Pa is controlled to be lower. Note that the control unit 14 may switch the allowable charging power Pa in stages, for example from an initial value of 100% to 95%, 90%, and so forth, in accordance with the calculated amount of Li deposition.

Accordingly, the battery management device 10 according to the present disclosure can set the highest possible allowable charging power Pa for the secondary battery 20 that enables efficient charging in the shortest possible charging time, while suppressing Li deposition. That is to say, the battery management device 10 according to the present disclosure can set the allowable charging power Pa for the secondary battery 20 to an appropriate value in accordance with the amount of Li deposition, without being set excessively low, thereby enabling efficient charging of the secondary battery 20 to be realized.

However, the detection value of the real part Z of the alternating current impedance from the impedance detecting unit 12 may include error due to effects of delay in circuit operation, sensitivity of the circuit, noise, and the like. Therefore, the battery management device 10 according to the present embodiment performs an operation test regarding the impedance detecting unit 12 before normal operation, and corrects the detected error by the correction unit 16. Thus, the battery management device 10 according to the present embodiment can precisely detect the amount of Li deposited in the secondary battery 20.

First, a specific configuration example of the impedance detecting unit 12 will be described below, and then types of errors that can occur in the impedance detecting unit 12, and correction thereof by the correction unit 16, will be described.

Specific Configuration Example of Impedance Detecting Unit 12

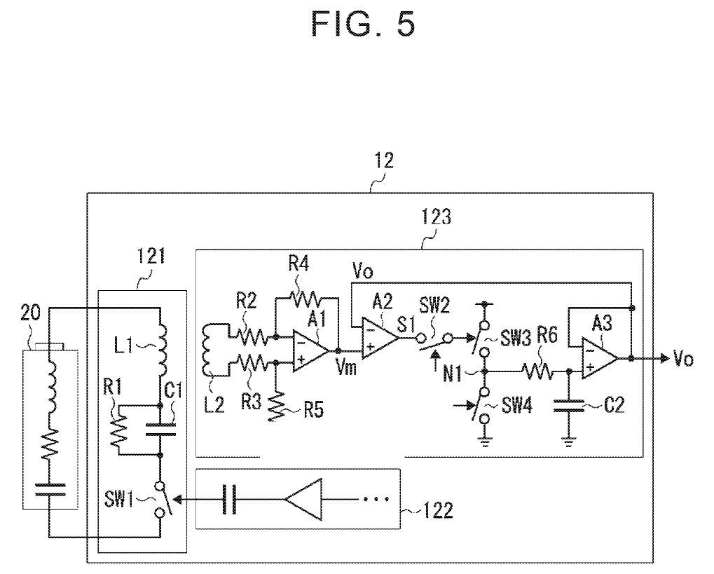

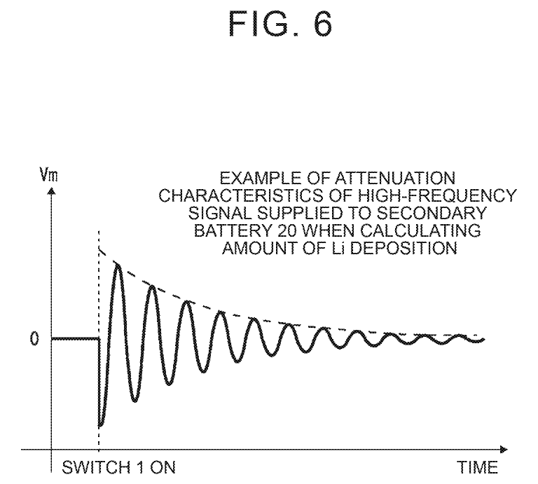

FIG. 5 is a diagram illustrating a specific example of a configuration of the impedance detecting unit 12 provided in the battery management device 10. The secondary battery 20 is also illustrated in FIG. 5. FIG. 6 is a diagram showing attenuation characteristics of a high-frequency signal supplied from the high-frequency signal supplying unit 11 to the secondary battery 20 when calculating the amount of Li deposition.

As illustrated in FIG. 5, the impedance detecting unit 12 includes a resonance circuit 121, a trigger signal output circuit 122, and a peak holding circuit 123. The impedance detecting unit 12 is also called an impedance detecting circuit. The resonance circuit 121 corresponds to the high-frequency signal supplying unit 11.

The resonance circuit 121 is a circuit that resonates at a high frequency (frequency of the frequency signal from high-frequency signal supplying unit 11).

Specifically, the resonance circuit 121 includes an inductor L1, a capacitor C1, a resistive element R1, and a switch SW1. The resistive element R1 is provided in parallel with the capacitor C1. The inductor L1, the capacitor C1, and the switch SW1 are provided being connected in series between the cathode and the anode of the secondary battery 20. The trigger signal output circuit 122 activates a trigger signal based on an instruction from the control unit 14, for example, thereby temporarily turning on the switch SW1. When the switch SW1 is turned on, the resonance circuit 121 starts resonating at a high frequency.

The peak holding circuit 123 detects the value of the real part Z of the alternating current impedance of the secondary battery 20, from the attenuation characteristics of the high-frequency signal supplied to the secondary battery 20.

Specifically, the peak holding circuit 123 includes an inductor L2, resistive elements R2 to R6, amplifiers A1 to A3, and switches SW2 to SW4. The inductor L2 is magnetically coupled to the inductor L1 and receives the high-frequency signal flowing through the inductor L1. The resistive element R2 is provided between one end of the inductor L2 and an inverting input terminal of the amplifier A1. The resistive element R3 is provided between another end of the inductor L2 and a non-inverting input terminal of the amplifier A1. The resistive element R4 is provided between an output terminal and the inverting input terminal of the amplifier A1. The resistive element R5 is provided between the non-inverting input terminal of the amplifier A1 and the ground. The amplifier A1 amplifies the high-frequency signal received by the inductor L2 from the inductor L1 and outputs the amplified signal as an output voltage Vm.

The amplifier (hereinafter, comparator) A2 compares the output voltage Vm of the amplifier A1 (amplified voltage of high-frequency signal) with output voltage Vo of the amplifier A3 (output voltage of peak holding circuit 123), and outputs a comparison result S1. When the output voltage Vm of the amplifier A1 is lower than the output voltage Vo of the amplifier A3, for example, the comparator A2 outputs an L-level comparison result

S1, and when the output voltage Vm of the amplifier A1 is equal to or greater than the output voltage Vo of the amplifier A3, outputs an H-level comparison result S1.

The switch SW2 is provided between an output terminal of the amplifier A2 and a control terminal of the switch SW3, and is controlled to be turned off during initialization and to be turned on otherwise. Note, however, when signals of a plurality of different frequencies are input for different periods, and obtaining just an amplitude of a signal of a certain specific frequency is desired, the switch SW2 may be controlled to be on only during the period in which the signal of that specific frequency is input, and may be turned off otherwise.

The switch SW3 is provided between a power supply voltage terminal to which a power supply voltage is supplied, and a node N1. The switch SW4 is provided between the node N1 and the ground. The resistive element R6 is provided between the node N1 and a non-inverting input terminal of the amplifier A3. An output terminal and an inverting input terminal of the amplifier A3 are connected to each other. The capacitor C2 is provided between the non-inverting input terminal of the amplifier A3 and the ground. The switch SW3 is turned off when the L-level comparison result S1 of the amplifier A2 is supplied via the switch SW2, and is turned on when the H-level comparison result S1 of the amplifier A2 is supplied via the switch SW2. The switch SW4 is controlled to be turned on when the charge stored in the capacitor C2 is to be released to the ground during initialization, and is otherwise turned off.

For example, when the output voltage Vm of the amplifier A1 is lower than the output voltage Vo of the amplifier A3, the switch SW3 remains off, and accordingly no additional charge is stored in the capacitor C2. Thus, the amplifier A3 maintains the output voltage Vo at the current value. On the other hand, when the output voltage Vm of the amplifier A1 is equal to or higher than the output voltage Vo of the amplifier A3, the switch SW3 turns on, and accordingly additional charge is stored in the capacitor C2 for the period during which the switch SW3 is on. This causes the amplifier A3 to increase the output voltage Vo by a value corresponding to the increase in the charge. Repeating this process causes the output voltage Vo to gradually approach the peak voltage of the high-frequency signal, and finally reach the peak voltage of the high-frequency signal or a voltage equivalent thereto. Thus, the peak holding circuit 123 detects the peak voltage (Vo) of the high-frequency signal.

Note that the peak holding circuit 123 detects the attenuation characteristics of the high-frequency signal based on peak voltages of the high-frequency signal at two or more points, and detection intervals of these peak voltages. That is to say, the peak holding circuit 123 detects the attenuation characteristics of the high-frequency signal from the amount of change in the peak voltage Vo per unit time. Note that calculation of the attenuation characteristics of the high-frequency signal may be performed in the calculation unit 13.

Detection Error of Peak Voltage Vo Caused by Feedback Delay

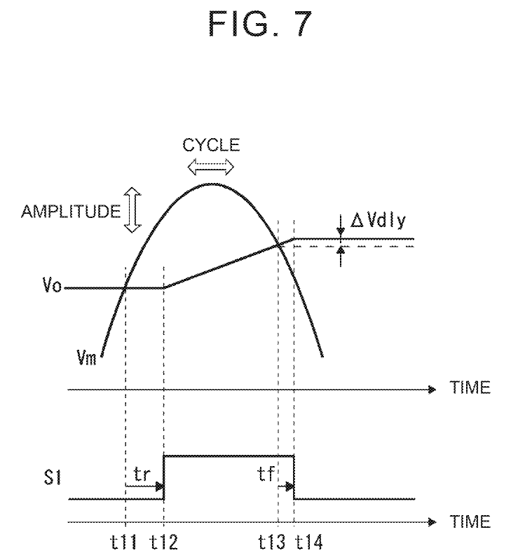

FIG. 7 is a timing chart for describing detection error of the peak voltage Vo that is caused by feedback delay. Note that FIG. 7 shows one of signal waveforms that is convex in a positive direction, from among the high-frequency signals represented by the voltage Vm.

As shown in FIG. 5, in the peak holding circuit 123, the output voltage Vo of the amplifier A3 (output voltage of peak holding circuit 123) is fed back to the comparator A2. The comparator A2 compares the output voltage Vo of the amplifier A3 that is fed back, with the output voltage (amplified voltage of high-frequency signal) Vm of amplifier A1, and outputs the comparison result S1. Now, as shown in FIG. 7, due to the effects of the feedback delay of the voltage Vo, following the voltage Vm starting to rise and becoming equal to or greater than the voltage Vo (time t11), the comparison result S1 of the comparator A2 rises after a time tr has elapsed (time t12), and following the voltage Vm peaking and starting to fall to lower than the voltage Vo (time t13), the comparison result falls after a time tf has elapsed (time t14). Accordingly, the output voltage (peak voltage) Vo includes error of a voltage ΔVdly as compared to when there is no feedback delay. Rising delay tr of the signal does not pose a problem here, due to being included in the detection error of the peak voltage Vo, which will be described later. Note that this error voltage ΔVdly differs depending on the amplitude and the cycle of the high-frequency signal.

Accordingly, the correction unit 16 performs correction of the output voltage Vo of the peak holding circuit 123 so as to cancel out the error voltage ΔVdly, which indicates a value in accordance with the amplitude and the cycle of the high-frequency signal. Note that a plurality of combinations of the amplitude and the cycle of the high-frequency signal and the corresponding error voltage ΔVdly is stored in the storage unit 15, for example.

Accordingly, the correction unit 16 extracts the error voltage ΔVdly corresponding to the amplitude and the cycle of the high-frequency signal from the storage unit 15 and adds this to the output voltage Vo of the peak holding circuit 123. This suppresses the detection error of the peak voltage Vo caused by the feedback delay.

Detection Error of Peak Voltage Vo Caused by Sensitivity of Comparator A2

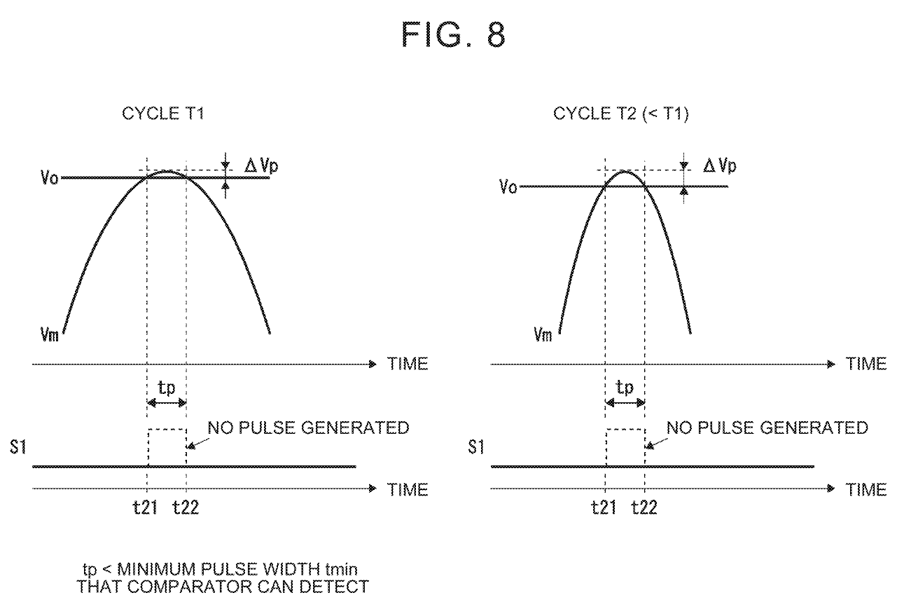

FIG. 8 is a timing chart for describing detection error of the peak voltage Vo caused by sensitivity of the comparator A2. Note that FIG. 8 shows one of the signal waveforms that is convex in the positive direction, from among the high-frequency signals represented by the voltage Vm.

As illustrated in FIG. 5, in the peak holding circuit 123, the comparator A2 compares the output voltage Vo of the amplifier A3 that is fed back, with the output voltage (amplified voltage of high-frequency signal) Vm of the amplifier A1, and outputs the comparison result S1. Here, as shown in FIG. 8, when a period tp during which the voltage Vm is equal to or greater than the voltage Vo is shorter than a minimum pulse width tmin that the comparator A2 can detect, the comparator A2 cannot raise the comparison result S1 during the period tp from time t21 to t22 during which the voltage Vm is equal to or greater than the voltage Vo. Accordingly, the output voltage (peak voltage) Vo includes error of voltage ΔVp, as compared to when the comparison result S1 rises in the period tp from time t21 to t22. Note that as can be seen by comparing the right and left diagrams in FIG. 8, this error voltage ΔVp differs depending on the cycle of the high-frequency signal.

Accordingly, the correction unit 16 performs correction of the output voltage Vo of the peak holding circuit 123 so as to cancel out the error voltage ΔVp, which indicates a value according to the cycle of the high-frequency signal. Note that a plurality of combinations of the cycle of the high-frequency signal and the corresponding error voltage ΔVp is stored in the storage unit 15, for example. Accordingly, the correction unit 16 extracts the error voltage ΔVp corresponding to the cycle of the high-frequency signal from the storage unit 15 and adds this to the output voltage Vo of the peak holding circuit 123. This suppresses the detection error of the peak voltage Vo caused by the sensitivity of the comparator A2.

Detection Error of Peak Voltage Vo Caused by Noise

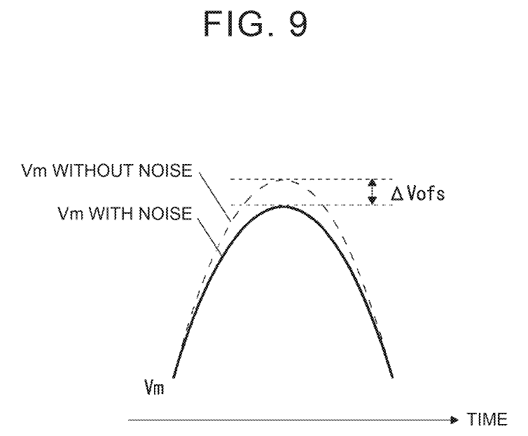

FIG. 9 is a timing chart for describing detection error of the peak voltage Vo caused by noise. Note that FIG. 9 shows one of the signal waveforms that is convex in the positive direction, from among the high-frequency signals represented by the voltage Vm.

As shown in FIG. 9, the peak of the voltage Vm fluctuates due to various types of noises such as white noise, environmental noise, and the like. In the example of FIG. 9, the voltage Vm includes error of a voltage ΔVofs as compared to when there is no noise. Since the voltage Vm includes the error voltage ΔVofs, the voltage Vo also includes the error voltage ΔVofs, as a matter of course. This error voltage ΔVofs differs depending on the magnitude of noise (amount of noise) that varies depending on usage status of the secondary battery 20. The usage status of the secondary battery 20 refers to, for example, traveling conditions of the vehicle in which the secondary battery 20 is installed, charging conditions of the secondary battery 20, and the like.

Therefore, the correction unit 16 performs correction of the output voltage Vo of the peak holding circuit 123 so as to cancel out the error voltage ΔVofs indicating a value in accordance with the usage status (amount of noise) of the secondary battery 20. Note that a plurality of combinations of the usage status (amount of noise) of the secondary battery 20 and the corresponding error voltage ΔVofs is stored in the storage unit 15, for example. Accordingly, the correction unit 16 extracts the error voltage ΔVofs corresponding to the usage status (amount of noise) of the secondary battery 20 from the storage unit 15 and adds this to the output voltage Vo of the peak holding circuit 123. This suppresses detection errors in the peak voltage Vo caused by the usage status of the secondary battery 20.

In the examples of FIGS. 7 to 9, the error voltages ΔVdly, ΔVp, and ΔVofs are each stored individually in the storage unit 15, but this is not restrictive. For example, the error voltages ΔVdly, ΔVp, and ΔVofs may be integrated into an error voltage ΔVerr, and stored in the storage unit 15. In this case, the correction unit 16 performs correction of the output voltage Verr of the peak holding circuit 123 so as to cancel out the error voltage Verr. A method for acquiring the error voltage ΔVerr stored in the storage unit 15 will be described below.

First, in a test mode, from among operation modes that include a normal operation mode and a test mode, the control unit 14 causes the three-phase inverter 30 to generate an alternating current signal that is a test signal with an amplitude and cycle (pulse width) in accordance with test content. This test signal is an alternating current signal having a frequency approximately equal to that of the high-frequency signal generated by the high-frequency signal supplying unit 11. This test signal generated by the three-phase inverter 30 is supplied to the secondary battery 20. Also, the control unit 14 controls the switch SW1 to on.

The calculation unit 13 then extracts difference between the peak voltage Vo of the test signal detected by the impedance detecting unit 12 and a theoretical value of the peak voltage Vo of the test signal that would ideally be detected by the impedance detecting unit 12 (e.g., error voltage ΔVerr). The information regarding the error voltage ΔVerr that is extracted is stored in the storage unit 15.

Note that the theoretical value of the peak voltage Vo that would ideally be detected by the impedance detecting unit 12 is calculated by the calculation unit 13 or the like, based on, for example, information regarding the amplitude and the cycle of the test signal that the control unit 14 instructs the three-phase inverter 30 to generate, information acquired from the design specifications of the impedance detecting unit 12 and the results of the evaluation test (e.g., information regarding sensitivity of the comparator A2 and delay time required for feeding back the output voltage Vo from the amplifier A3 to the comparator A2, etc.), and so forth.

The control unit 14 causes the three-phase inverter 30 to supply a plurality of test signals with various types of cycles and amplitudes to the secondary battery 20. Alternatively, the control unit 14 causes the secondary battery 20 to supply a plurality of test signals to which noises of various amounts of noise have been added. The calculation unit 13 extracts the difference between the detected value of the peak voltage Vo of each of the test signals and the theoretical value of the peak voltage Vo of the corresponding test signal (e.g., error voltage ΔVerr), and stores this in the storage unit 15. Thus, the storage unit 15 stores a plurality of combinations of high-frequency signals with different waveform patterns, and the error voltages ΔVerr corresponding thereto.

As a result, the battery management device 10 can precisely correct detection error of the impedance detecting unit 12 even when the amplitude and the cycle of the high-frequency signal, or the usage conditions (amount of noise) of the secondary battery 20, are different, and accordingly can precisely detect the amount of Li deposition in the secondary battery 20.

In this way, the battery management device 10 according to the present disclosure can set the highest possible allowable charging power Pa for the secondary battery 20 that enables efficient charging in the shortest possible charging time, while suppressing Li deposition. That is to say, the battery management device 10 according to the present disclosure can set the allowable charging power Pa for the secondary battery 20 to an appropriate value in accordance with the amount of Li deposition, without being set excessively low, thereby enabling efficient charging of the secondary battery 20 to be realized.

Further, the battery management device 10 according to the present disclosure can precisely correct detection error of the impedance detecting unit 12 even when the amplitude and the cycle of the high-frequency signal, or the usage conditions (amount of noise) of the secondary battery 20, are different, and accordingly can precisely detect the amount of Li deposition in the secondary battery 20.

The present disclosure can be realized by causing a central processing unit (CPU) to execute a computer program for part or all of the processing of the battery management device 10.

The program that is described above includes a set of instructions (or software code) for causing a computer to perform one or more functions described in the embodiment when the program is loaded to the computer. The program may be stored in a non-transitory computer-readable medium or a tangible storage medium. By way of example and not limitation, computer-readable media or tangible storage media include random-access memory (RAM), read-only memory (ROM), flash memory, solid-state drive (SSD) and other memory technology, compact disc read-only memory (CD-ROM), digital versatile disc (DVD), Blu-ray (registered trademark) Disc or other optical disk storage, magnetic cassette, magnetic tape, magnetic disk storage, and other magnetic storage devices. The program may be transmitted on a transitory computer-readable medium or a communication medium. By way of example and not limitation, the transitory computer-readable medium or the communication medium includes electrical, optical, acoustic signals, or other form of propagation signals.

Although the present disclosure has been described above by way of the

embodiment, the present disclosure is not limited to the above embodiment. Various modifications that would be understood by a person skilled in the art can be made with respect to the configuration and details of the present disclosure within the scope of the present disclosure. Moreover, each embodiment can be combined with other embodiments as appropriate.

What is claimed is:

1. A battery management system comprising at least:
a three-phase inverter driven by power from a lithium-ion secondary battery; and
an impedance detecting unit that detects two or more peak voltages of a high-frequency signal in the lithium-ion secondary battery, calculates an attenuation characteristic, and detects, from the attenuation characteristic that is calculated, a value of a real part of an alternating current impedance used to calculate an amount of Li deposition, wherein
the battery management system further includes
a control unit that supplies an alternating current signal that is a test signal generated by the three-phase inverter to the lithium-ion secondary battery in a test mode, and
a correction unit that performs correction of a value of peak voltage of the high-frequency signal corresponding to the test signal that is detected by the impedance detecting unit, based on a difference between the peak voltage of the test signal detected by the impedance detecting unit and a theoretical value of the peak voltage of the test signal.

2. The battery management system according to claim 1, wherein the impedance detecting unit is configured to detect two or more peak voltages of the high-frequency signal, and calculate the attenuation characteristic of the high-frequency signal in the lithium-ion secondary battery based on detection results of the peak voltages and a detection interval between the peak voltages.

3. The battery management system according to claim 1, wherein the correction unit performs correction of the value of the peak voltage of the high-frequency signal at a cycle corresponding to the test signal detected by the impedance detecting unit, based on a difference between the peak voltage corresponding to the cycle of the test signal detected by the impedance detecting unit and the theoretical value of the peak voltage corresponding to the cycle of the test signal.

4. The battery management system according to claim 1, wherein the correction unit performs correction of the value of the peak voltage of the high-frequency signal of an amplitude corresponding to the test signal detected by the impedance detecting unit, based on a difference between the peak voltage corresponding to the amplitude of the test signal detected by the impedance detecting unit and the theoretical value of the peak voltage corresponding to the amplitude of the test signal.

5. The battery management system according to claim 1, wherein the correction unit performs correction of the value of the peak voltage of the high-frequency signal with an amount of noise corresponding to the test signal detected by the impedance detecting unit, based on a difference between the peak voltage corresponding to the amount of noise of the test signal detected by the impedance detecting unit and the theoretical value of the peak voltage corresponding to the amount of noise of the test signal.
